(19) United States
(12) Patent Application Publication
(10) Pub. No.: US 2012/0002488 A1
(43) Pub. Date: Jan. 5, 2012

(54) Current detection method

(75) Inventor: Zhongbo He, Chengdu (CN)

(73) Assignee: IPGoal Microelectronics (SiChuan) Co., Ltd.

(21) Appl. No.: 13/172,871

(22) Filed: Jun. 30, 2011

(30) Foreign Application Priority Data
Jun. 30, 2010 (CN) 201010213788.6

(51) Int. Cl. G11C 7/06

(52) U.S. Cl. 365/189.07

(57) ABSTRACT

A current detection method for detecting whether data are stored in a memory unit includes the steps of: (A) respectively inputting two currents into a detection current input end and a reference current end; (B) reading out a current of the detection current input end by a first switching element and a current of the reference current end by a second switching element; (C) respectively converting the current read out by the first switching element and the current read out by the second switching element into two voltages, and respectively transmitting the two voltages to two input ends of a comparator; and (D) outputting a voltage signal for determining whether the data are stored in the memory unit by the comparator. The current detection method of the present invention has the fast detection speed, low power consumption and simple operation.

### BACKGROUND OF THE PRESENT INVENTION

1. Field of Invention

The present invention relates to a detection method, and more particularly to a current detection method which is adapted for the one time programmable read-only memory (OTP-ROM).

2. Description of Related Arts

Read-only memory (ROM) is a solid-state semiconductor memory which can only read out the data stored in advance. The stored data are generally written into the ROM before the ROM is installed into the complete set. During the operation process of the complete set, the stored data can only be read out by the ROM rather than the stored data can be quickly and conveniently rewritten by the random access memory (RAM). The data stored in the ROM are stable and can not be changed after power-off. The ROM has the simple structure and facilitates reading out the data, so it is often used to store various fixed programs and data.

One time programmable read-only memory (OTP-ROM) is one of ROMs, into which the data can only be written once. To determine the situations of the data stored in the memory, it is necessary to provide a current detection method for detecting whether the data are stored in the memory. However, the traditional current detection method is complicated.

### SUMMARY OF THE PRESENT INVENTION

An object of the present invention is to provide current detection method which is adapted for the one time programmable read-only memory (OTP-ROM).

Accordingly, in order to accomplish the above object, the present invention provides a current detection method for detecting whether data are stored in a memory unit, comprising the steps of:

(A) respectively inputting two currents into a detection current input end and a reference current end;

(B) reading out a current of the detection current input end by a first switching element and a current of the reference current end by a second switching element;

(C) respectively converting the current read out by the first switching element and the current read out by the second switching element into two voltages, and respectively transmitting the two voltages to two input ends of a comparator; and

(D) outputting a voltage signal for determining whether the data are stored in the memory unit by the comparator.

Compared with the prior art, the current detection method of the present invention can determine whether the data are stored in the memory based on the outputted high and low levels. Therefore, it is easy and convenient.

These and other objectives, features, and advantages of the present invention will become apparent from the following detailed description, the accompanying drawings, and the appended claims.

### BRIEF DESCRIPTION OF THE DRAWINGS

FIG. 1 is a circuit diagram of a current detection circuit based on a current detection method according to a preferred embodiment of the present invention.

FIG. 2 is a flow chart of the current detection method according to the above preferred embodiment of the present invention.

### DETAILED DESCRIPTION OF THE PREFERRED EMBODIMENT

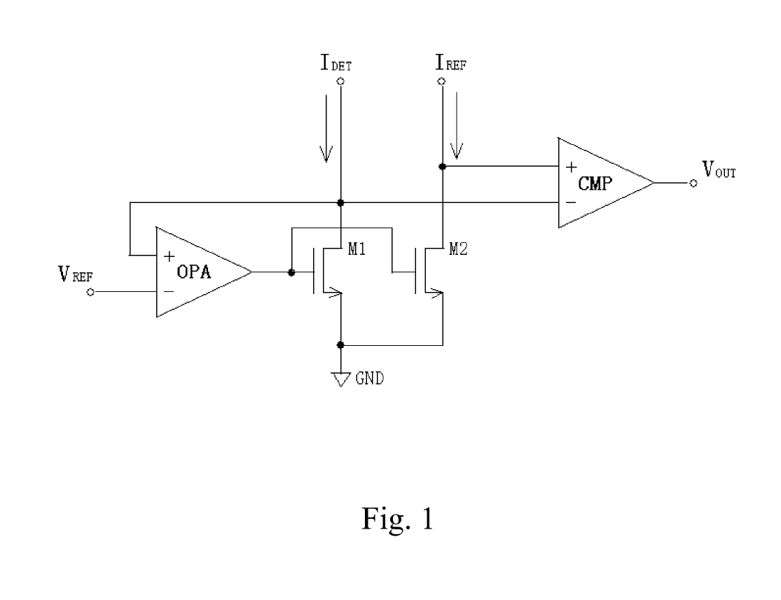

Referring to FIG. 1 of the drawings, a current detection circuit based on a current detection method according to a preferred embodiment of the present invention is illustrated, wherein the current detection circuit comprises a detection current input end I_{DET}, a reference current end I_{REF}, a first switching element connected with the detection current input end I_{DET}, a second switching element connected with the reference current end I_{REF}, an operational amplifier OPA, a comparator CMP, a reference voltage end V_{REF}, an output end Y_{OUT} and a ground end GND. The detection current input end I_{DET} is connected with a memory unit of a memory.

In the preferred embodiment of the present invention, the first switching element is a first field effect transistor (FET) M1, the second switching element is a second field effect transistor (FET) M2, and the first FET M1 and the second FET M2 are N-type FETs (NMOS). In other preferred embodiments, these FETs can be replaced by other switching components or circuits which are capable of achieving the same function as required.

The specific connection relations of the current detection circuit of the present invention are described as follows. The detection current input end I_{DET}, the drain electrode of the first FET M1, the positive input end of the operational amplifier OPA and a negative input end of the comparator CMP are connected with each other. The reference current end I_{REF}, the drain electrode of the second FET M2 and the positive input end of the comparator CMP are connected with each other. The source electrode of the first FET M1 and the source electrode of the second FET M2 are connected with the ground end GND. The negative input end of the operational amplifier OPA is connected with the reference voltage end V_{REF}. The output end of the operational amplifier OPA is connected with the grid electrode of the first FET M1 and the grid electrode of the second FET M2. The output end of the comparator CMP is connected with the output end V_{OUT}.

The drain voltage of the first FET M1 is equal to the voltage of the reference voltage end V_{REF} by the operational amplifier OPA, thereby providing an appropriate bias voltage for the memory unit. Simultaneously, the output end of the operational amplifier OPA is connected with the grid electrode of the first FET M1 and the grid electrode of the second FET M2, so that a mirror image relationship is provided between the first FET M1 and the second FET M2 to provide an appropriate bias voltage for the first FET M1 and the second FET M2. The first FET M1 is adapted for reading out the current of the detection current input end I_{DET}. The second FET M2 is adapted for reading out the current of the reference current end I_{REF}. When the data are stored in the memory unit, the current of the detection current input end I_{DET} will be larger than that of the current of the reference current end I_{REF}. When no data is stored in the memory unit, no current passes through the detection current input end I_{DET}, or the current of the detection current input end I_{DET} will be smaller than that of the current of the reference current end I_{REF}.

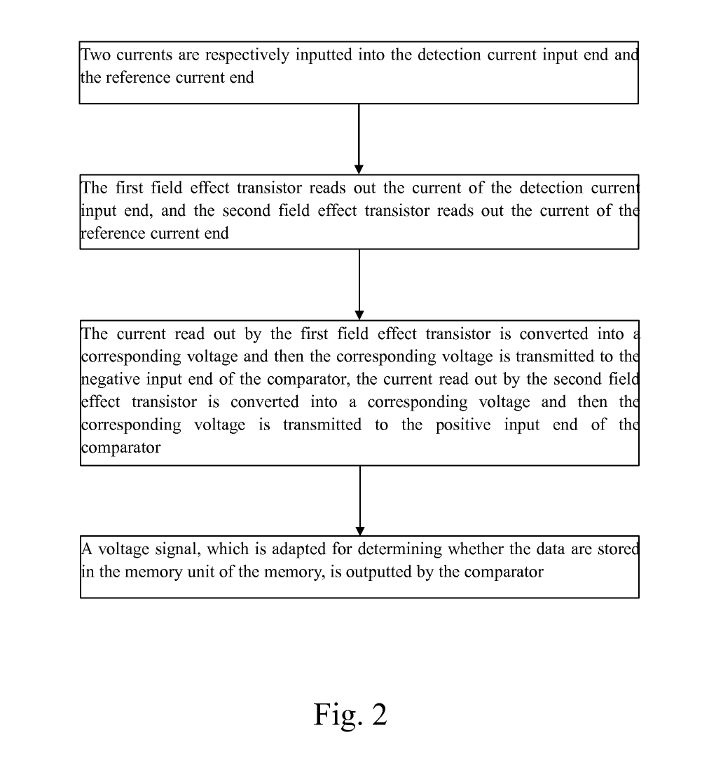

Referring to FIG. 2, the current detection method according to the preferred embodiment of the present invention comprises the steps as follow.

(1) Two currents are respectively inputted into the detection current input end I_{DET} and the reference current end I_{REF}.

(2) The first FET M1 reads out the current of the detection current input end I_{DET}, and the second FET M2 reads out the current of the reference current end I_{REF}.

(3) The current read out by the first FET M1 is converted into a corresponding voltage and then the corresponding voltage is transmitted to the negative input end of the comparator CMP by the first FET M1. The current read out by the second FET M2 is converted into a corresponding voltage and then the corresponding voltage is transmitted to the positive input end of the comparator CMP by the second FET M2.

(4) A voltage signal, which is adapted for determining whether the data are stored in the memory unit of the memory, is outputted by the comparator CMP. When the first FET M1 and the second FET M2 read out that the detection current input end I_{DET} is larger than that of the current of the reference current end I_{REF}, the voltage of the negative input end of the comparator CMP is larger than the voltage of the positive input end of the comparator CMP, so that the output end of the comparator CMP outputs a low level to the output end V_{OUT}, thereby it is proved that the data are stored in the memory unit of the memory. When the first FET M1 and the second FET M2 read out that the detection current input end I_{DET} is smaller than that of the current of the reference current end I_{REF}, the voltage of the negative input end of the comparator CMP is smaller than the voltage of the positive input end of the comparator CMP, so that the output end of the comparator CMP outputs a high level to the output end V_{OUT}, thereby it is proved that no data is stored in the memory unit of the memory.

Based on the high and low levels outputted by the output end V_{OUT}, whether the data are stored in the memory is detected by the current detection method of the present invention. The current detection method of the present invention has the fast detection speed, low power consumption and simple operation.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A current detection method for detecting whether data are stored in a memory unit, comprising:
(A) respectively inputting two currents into a detection current input end and a reference current end;
(B) reading out a current of the detection current input end by a first switching element and a current of the reference current end by a second switching element;
(C) respectively converting the current read out by the first switching element and the current read out by the second switching element into two voltages, and respectively transmitting the two voltages to two input ends of a comparator; and
(D) outputting a voltage signal for determining whether the data are stored in the memory unit by the comparator.

2. The current detection method, as recited in claim 1, wherein the first switching element is a first field effect transistor and the second switching element is a second field effect transistor.

3. The current detection method, as recited in claim 2, wherein a drain electrode of the first field effect transistor is connected with the detection current input end, a drain electrode of the second field effect transistor is connected with the reference current end, a grid electrode of the first field effect transistor and a grid electrode of the second field effect transistor are connected with an operational amplifier, a source electrode of the first field effect transistor and a source electrode of the second field effect transistor are connected with a ground.

4. The current detection method, as recited in claim 3, wherein a negative input end of the operational amplifier is connected with a reference voltage end, a positive input end of the operational amplifier and the drain electrode of the first field effect transistor are connected with the detection current input end, an output end of the operational amplifier is connected with the grid electrode of the first effect transistor and the grid electrode of the second field effect transistor.

5. The current detection method, as recited in claim 4, wherein a negative input end of the comparator, the drain electrode of the first field effect transistor and the positive input end of the operational amplifier are connected with the detection current input end, a positive input end of the comparator and the drain electrode of the second field effect transistor are connected with the reference current end.

6. The current detection method, as recited in claim 5, wherein the first and second field effect transistors are NMOS transistors.

7. The current detection method, as recited in claim 1, wherein when the current of the detection current input end read out by the first switching element is larger than the current of the reference current end read out by the second switching element, a voltage of a negative input end of the comparator is larger than a voltage of a positive input end of the comparator, an output end of the comparator outputs a low level, thereby the data are stored in the memory unit; when the current of the detection current input end read out by the first switching element is smaller than the current of the reference current end read out by the second switching element, a voltage of a negative input end of the comparator is smaller than a voltage of a positive input end of the comparator, an output end of the comparator outputs a high level, thereby no data is stored in the memory unit.

8. The current detection method, as recited in claim 2, wherein when the current of the detection current input end read out by the first switching element is larger than the current of the reference current end read out by the second switching element, a voltage of a negative input end of the comparator is larger than a voltage of a positive input end of the comparator, an output end of the comparator outputs a low level, thereby the data are stored in the memory unit; when the current of the detection current input end read out by the first switching element is smaller than the current of the reference current end read out by the second switching element, a voltage of a negative input end of the comparator is smaller than a voltage of a positive input end of the comparator, an output end of the comparator outputs a high level, thereby no data is stored in the memory unit.

9. The current detection method, as recited in claim 3, wherein when the current of the detection current input end read out by the first switching element is larger than the current of the reference current end read out by the second switching element, a voltage of the negative input end of the comparator is larger than a voltage of the positive input end of the comparator, the output end of the comparator outputs a low level, thereby the data are stored in the memory unit; when the current of the detection current input end read out by the first switching element is smaller than the current of the reference current end read out by the second switching element, a voltage of the negative input end of the comparator is smaller than a voltage of the positive input end of the comparator, the output end of the comparator outputs a high level, thereby no data is stored in the memory unit.

10. The current detection method, as recited in claim 4, wherein when the current of the detection current input end read out by the first switching element is larger than the current of the reference current end read out by the second switching element, a voltage of the negative input end of the comparator is larger than a voltage of the positive input end of the comparator, the output end of the comparator outputs a low level, thereby the data are stored in the memory unit; when the current of the detection current input end read out by the first switching element is smaller than the current of the reference current end read out by the second switching element, a voltage of the negative input end of the comparator is smaller than a voltage of the positive input end of the comparator, the output end of the comparator outputs a high level, thereby no data is stored in the memory unit.

11. The current detection method, as recited in claim 5, wherein when the current of the detection current input end read out by the first switching element is larger than the current of the reference current end read out by the second switching element, a voltage of the negative input end of the comparator is larger than a voltage of the positive input end of the comparator, the output end of the comparator outputs a low level, thereby the data are stored in the memory unit; when the current of the detection current input end read out by the first switching element is smaller than the current of the reference current end read out by the second switching element, a voltage of the negative input end of the comparator is smaller than a voltage of the positive input end of the comparator, the output end of the comparator outputs a high level, thereby no data is stored in the memory unit.

12. The current detection method, as recited in claim 6, wherein when the current of the detection current input end read out by the first switching element is larger than the current of the reference current end read out by the second switching element, a voltage of the negative input end of the comparator is larger than a voltage of the positive input end of the comparator, the output end of the comparator outputs a low level, thereby the data are stored in the memory unit; when the current of the detection current input end read out by the first switching element is smaller than the current of the reference current end read out by the second switching element, a voltage of the negative input end of the comparator is smaller than a voltage of the positive input end of the comparator, the output end of the comparator outputs a high level, thereby no data is stored in the memory unit.

13. A current detection circuit, comprising a detection current input end, a reference current end, a first field effect transistor connected with said detection current input end, a second field effect transistor connected with said reference current end, an operational amplifier, a comparator, a reference voltage end, an output end and a ground end,
wherein said detection current input end is connected with a memory unit of a memory,
wherein said detection current input end, a drain electrode of said first field effect transistor, a positive input end of said operational amplifier and a negative input end of said comparator are connected with each other, said reference current end, a drain electrode of said second field effect transistor and a positive input end of said comparator are connected with each other, a source electrode of said first field effect transistor and a source electrode of said second field effect transistor are connected with said ground end, a negative input end of said operational amplifier is connected with said reference voltage end, an output end of said operational amplifier is connected with a grid electrode of said first field effect transistor and a grid electrode of said second field effect transistor, an output end of said comparator is connected with said output end.

14. The current detection circuit, as recited in claim 13, wherein said first and second field effect transistors are NMOS transistors.
